(19) United States
(12) Patent Application Publication
(10) Pub. No.: US 2026/0296839 A1
(43) Pub. Date: Oct. 1, 2026

(54) OVERHEAD TRANSPORT VEHICLE

(71) Applicant: Murata Machinery, Ltd., Kyoto-shi, Kyoto (JP)

(72) Inventor: Eiji WADA, Kyoto-shi (JP)

(21) Appl. No.: 19/489,785

(22) PCT Filed: May 1, 2024
(86) PCT No.: PCT/JP2024/016775

§ 371 Date: Dec. 3, 2025

(30) Foreign Application Priority Data
Jun. 6, 2023 (JP) 2023-093147

(51) Int. Cl. B66C 1/28; B66C 1/22; B66C 17/06; H10P 72/30

(52) U.S. Cl. CPC B66C 1/28; B66C 1/223; B66C 17/06; H10P 72/3206; H10P 72/3214; H10P 72/3218; H10P 72/3221

(57) ABSTRACT

An overhead transport vehicle includes a traveler to travel along an overhead track, a main body to move along the overhead track together with the traveler, an elevation body suspended from the main body to ascend and descend relative to the main body, a holder fixed to a lower portion of the elevation body to hold an article, and a rigidity changer that to switch between a first rigidity state in which a rigidity between the main body and the holder is a first rigidity, and a second rigidity state in which a rigidity is a second rigidity higher than the first rigidity. The rigidity changer is configured to switch between the first rigidity state and the second rigidity state according to a traveling state of the overhead transport vehicle.

### BACKGROUND OF THE INVENTION

### 1. Field of the Invention

The present invention relates to overhead transport vehicles.

### 2. Description of the Related Art

An overhead transport vehicle that travels along an overhead track while holding an article has been disclosed (for example, see Japanese Unexamined Patent Application, First Publication No. 2006-8354). When transporting an article to a transfer destination, this overhead transport vehicle travels along an overhead track while holding the article, transporting it to a predetermined transport position. The overhead transport vehicle then performs a transfer operation at the transport position, such as laterally extending or lowering the article, to transfer the article to the transfer destination.

### SUMMARY OF THE INVENTION

In an overhead transport vehicle, suppressing vibration and sway of the article being held is important from the viewpoint of improving transport capacity and transfer capability.

Example embodiments of the present invention provide overhead transport vehicles that reduce or prevent vibration and sway of an article.

An overhead transport vehicle according to an example embodiment of the present invention is an overhead transport vehicle that travels along an overhead track while holding an article, including a traveler to travel along the overhead track, a main body to move along the overhead track together with the traveler, an elevation body suspended from the main body to ascend and descend relative to the main body, a holder fixed to a lower portion of the elevation body to hold the article, and a rigidity changer to switch between a first rigidity state in which a rigidity between the main body and the holder is a first rigidity, and a second rigidity state in which a rigidity is a second rigidity higher than the first rigidity, wherein the rigidity changer is configured to switch between the first rigidity state and the second rigidity state according to a traveling state of the overhead transport vehicle.

Overhead transport vehicles according to example embodiments of the present invention reduce or prevent vibration transmitted to an article and reduce the likelihood of the article swaying by switching the rigidity between the main body and the holder according to the traveling state of the overhead transport vehicle, including a stop state, and it is thus possible to reduce or prevent vibration and sway of the article according to the state of the overhead traveling vehicle.

According to an overhead transport vehicle according to an example embodiment of the present invention, the rigidity changer may be configured to switch to the first rigidity state when a speed of the overhead transport vehicle is equal to or higher than a first speed, and switch to the second rigidity state when the speed of the overhead transport vehicle is equal to or less than a second speed lower than the first speed, or when the overhead transport vehicle is stationary. According to such a configuration, vibration to the article during travel and sway of the article during transfer are effectively reduced or prevented.

According to an overhead transport vehicle according to an example embodiment of the present invention, the rigidity between the main body and the holder may be either one or both of a connection rigidity, which is a rigidity between the main body and the elevation body and a holding rigidity, which is a rigidity between the elevation body and the article, in a state where the holder is holding the article. According to such a configuration, vibration to the article during travel and sway of the article during transfer are effectively reduced or prevented.

According to an overhead transport vehicle according to an example embodiment of the present invention, the rigidity changer may include an elastic body provided between the main body and an upper portion of the elevation body, the main body may include an elevation driver to adjust a compression amount of the elastic body by adjusting a position of the elevation body, and to change the connection rigidity by changing the compression amount of the elastic body. According to such a configuration, vibration to the article during travel and sway of the article during transfer are effectively reduced or prevented.

According to an overhead transport vehicle according to an example embodiment of the present invention, the rigidity changer may include a support that is provided at a lower portion of the elevation body and movable in an up-down direction according to an ascending/descending operation of the elevation body, a presser that is provided at a lower portion of the support to press the article held by the holder downward, and an elastic body provided between the support and the presser, the main body may include an elevation driver to adjust a compression amount of the elastic body by adjusting a position of the elevation body and to change the holding rigidity by changing the compression amount of the elastic body. According to such a configuration, vibration to the article during travel and sway of the article during transfer are effectively reduced or prevented.

According to an overhead transport vehicle according to an example embodiment of the present invention, the rigidity changer may include a receiver provided at an upper portion of the elevation body, a first elastic body provided between the receiver and the upper portion of the elevation body, a support provided at a lower portion of the elevation body, a connector to connect the receiver and the support, a presser that is provided at a lower portion of the support to press the article held by the holder downward, and a second elastic body provided between the support and the presser, the main body may include an elevation driver to adjust the compression amount of the first elastic body and the second elastic body by adjusting the position of the elevation body with the receiver in contact with the main body, an increase in the compression amount of the first elastic body and the second elastic body causes an increase in the connection rigidity and the holding rigidity may become, and when in the first rigidity state, the compression amount of the first elastic body and the second elastic body may be controlled to be a first compression amount, and when in the second rigidity state, the compression amount of the first elastic body and the second elastic body may be controlled to be a second compression amount that is higher than the first compression amount. According to such a configuration, vibration to the article during travel and sway of the article during transfer are even more effectively reduced or prevented.

According to an overhead transport vehicle according to an example embodiment of the present invention, the main body may include a lateral extender to move the elevation body laterally from the traveling direction and to move the elevation body laterally when in the second rigidity state. According to such a configuration, sway of the article during transfer is effectively reduced or prevented.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a diagram conceptually showing an overhead transport vehicle according to an example embodiment of the present invention.

FIG. 2 is a diagram schematically showing lateral transferer of an overhead transport vehicle according to an example embodiment of the present invention.

FIG. 3 is a diagram showing an initial state of an overhead transport vehicle according to an example embodiment of the present invention.

FIG. 4 is a diagram showing an overhead transport vehicle according to an example embodiment of the present invention holding a container.

FIG. 5 is a diagram showing an example of an accommodation state according to an example embodiment of the present invention.

FIG. 6 is a diagram for describing a vibration suppression state according to an example embodiment of the present invention.

FIG. 7 is a diagram for describing a sway suppression state according to an example embodiment of the present invention.

FIG. 8 is a diagram for describing an example of the flow of operations of an overhead transport vehicle according to an example embodiment of the present invention.

FIG. 9 is a diagram showing a first modified example of a rigidity changer according to an example embodiment of the present invention.

FIG. 10 is a diagram showing a second modified example of the rigidity changer according to an example embodiment of the present invention.

### DETAILED DESCRIPTION OF THE EXAMPLE EMBODIMENTS

Hereinafter, the present invention will be described with reference to example embodiments, and modifications or combinations thereof. However, the following example embodiments do not limit the present invention, and not all combinations of features described in the example embodiments are essential and maybe optional. In the drawings, the same or similar elements, features, etc., are denoted by the same reference signs, and redundant descriptions may be omitted. The shapes and sizes of elements, features, etc., in the drawings may be exaggerated for clarity, and the dimensions and shapes may differ from the actual product.

In the drawings, an XYZ Cartesian coordinate system is used to describe directions in each drawing. In the XYZ Cartesian coordinate system, a plane that is parallel or substantially parallel to a horizontal plane is defined as an XY plane. A direction along this XY plane is denoted as X direction, and a direction orthogonal to the X direction is denoted as Y direction. A direction perpendicular to the XY plane is denoted as Z direction. For each of the X direction, the Y direction, and the Z direction, description is made with a definition in which a direction indicated by an arrow is the positive (+) direction and a direction opposite to the direction indicated by the arrow is the negative (−) direction.

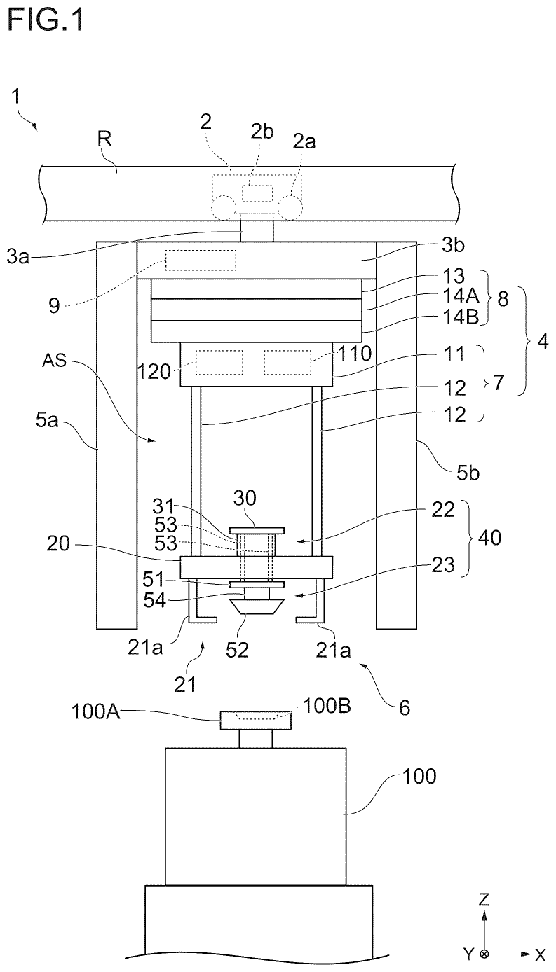

FIG. 1 is a diagram conceptually showing an overhead transport vehicle according to the present example embodiment. FIG. 1 conceptually shows an overhead transport vehicle 1 according to the present example embodiment as viewed from the-Y direction side.

The overhead transport vehicle 1 travels along a track R, which is provided at a position higher than the floor surface, such as on the ceiling of a clean room, and transports a container 100 in a suspended state within an accommodation space AS. The overhead transport vehicle 1 is used to transport containers 100, for example, between a processing apparatus and a container storage apparatus, or between two processing apparatuses. It should be noted that the X direction in FIG. 1 represents the traveling direction of the overhead transport vehicle 1. The Z direction in FIG. 1 represents the vertical direction of the overhead transport vehicle 1.

The overhead transport vehicle 1 is used to transport containers 100, for example, between a processing apparatus and a container storage apparatus, or between two processing apparatuses. These processing apparatuses are, for example, a film forming device, a coater/developer, an exposure device, or an etching device, and perform various processes during the manufacturing of devices (for example, semiconductor devices). The container storage apparatus mentioned above is arranged, for example, on a transport route along which the containers 100 are transported, and temporarily stores the containers 100. The container storage apparatus mentioned above is arranged, for example, in the vicinity of the ceiling. The containers 100 accommodate, for example, wafers or reticles used for manufacturing semiconductor devices. Examples of the containers 100 include a FOUP (Front Opening Unified Pod), a SMIF pod, and a reticle pod, the inside of which can be purged. The container 100 is an example of an “article”.

The overhead transport vehicle 1 includes, for example, a traveler 2, a coupler 3a, a support 3b, a main body 4, a cover 5a, a cover 5b, an elevator 6, and a controller 9.

The traveler 2 includes wheels 2a and a traveling driver 2b. The wheels 2a are arranged so as to be in contact with an overhead track R, and are driven to rotate by the driving force of the traveling driver 2b. The traveling driver 2b generates the driving force to cause the overhead transport vehicle 1 to travel. The traveling driver 2b includes, for example, a traveling motor such as a linear motor or a rotary motor. The traveling driver 2b has, for example, a rotary encoder or a linear encoder. The traveling driver 2b controls the linear motor or the rotary motor on the basis of detection results such as the rotation speed of the wheels 2a detected by the rotary encoder or the linear encoder, and controls the speed of stopping position of the overhead transport vehicle 1.

The coupler 3a couples the traveling driver 2b and the support 3b. For example, one end of the coupler 3a is connected to the traveling driver 2b and the other end to the support 3b. The support 3b is arranged along the horizontal plane and supports the main body 4.

The main body 4 is coupled to the traveling driver 2b via the coupler 3a and travels along the overhead track R together with the traveler 2. The main body 4 includes, for example, an elevation device 7 and a lateral extender 8. The elevation device 7 includes an elevation driver 11 and suspenders 12.

The elevation device 7 lowers or raises the elevator 6 at a predetermined speed, and maintains the elevator 6 at a target height. The elevator 6 is suspended from the main body 4 by multiple suspenders 12. The elevation driver 11 is, for example, a hoist, and lowers the elevator 6 by feeding out the multiple suspenders 12, and the elevation driver 11 raises the elevator 6 by winding up the multiple suspenders 12.

For example, the elevation driver 11 includes one or more rotating bodies 110 and an elevation motor 120. The rotation bodies 110 are, for example, cylindrical drums each having a winding surface for the suspender 12 on its outer circumference. The elevation motor 120 is an electric motor that rotates the rotating bodies 110 to wind up and feed out (unwind) the multiple suspenders 12. The elevation driver 11 may include rollers such as pulleys that support the multiple suspenders 12, for example. In the case where the elevator 6 is suspended using the suspenders 12, the elevation driver 11 only needs to have a configuration for winding up and feeding out the suspenders 12, and does not necessarily need to have the rotating body 110 and the suspenders 120.

The suspenders 12 each include one end connected to the elevation driver 11 and the other end connected to the elevator 6. The suspenders 12 are, for example, belts. In the present example embodiment, the elevator 6 is suspended from the main body 4 by, for example, three or four suspenders 12. However, the number of suspenders 12 is not particularly limited, provided there is more than one. For example, a conductive member such as a cable is provided within the suspender 12, and electric power is supplied from the main body 4 to the elevator 6 through this conductive member.

The lateral extender 8 performs a laterally extending operation in which the elevation driver 11 is moved laterally, in the left-right direction relative to the traveling direction of the main body 4. The traveling direction of the main body 4 is a direction in which the overhead transport vehicle 1 travels along the overhead track R via the traveler 2, that is, the X direction. The left-right direction is a direction orthogonal to the traveling direction, that is, the Y direction. The left-right direction is a direction in which the lateral extender 8 laterally extends the elevation driver 11, and is hereinafter referred to as lateral extension direction D.

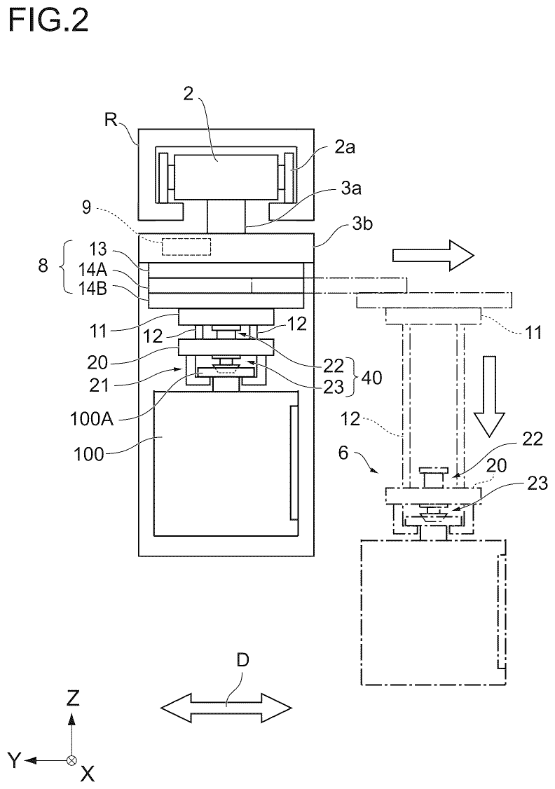

The lateral extender 8 includes, for example, a base 13 and one or more slides 14. The lateral extender 8 exemplified in FIG. 1 and FIG. 2 has two slides 14. One of the slides 14 is referred to as “first slide 14A,” and the other slide 14 is referred to as “second slide 14B”.

The base 13 is attached to a lower portion of the coupler 3a. The base 13 is attached to the support 3b, for example. The base 13 is, for example, a plate-shaped structure. The base 13 is arranged so that the plane of the base 13 is parallel or substantially parallel to the horizontal direction.

The first slide 14A is arranged on the lower surface side of the base 13. The first slide 14A is, for example, a plate-shaped structure, and is arranged so that its plane is parallel or substantially parallel to the plane of the base 13 in the Z direction. The first slide 14A has the same shape as the base 13. The first slide 14A is movable in the lateral extension direction D relative to the base 13.

The second slide 14B is arranged on the lower surface side of the first slide 14A. The second slide 14B is, for example, a plate-shaped structure, and is arranged so that its plane in the Z direction is parallel or substantially parallel to the plane of the base 13 and the plane of the first slide 14A. The second slide 14B has, for example, the same shape as the first slide 14A. The elevation driver 11 is provided on the lower surface of the second slide 14B. The second slide 14B is movable in the lateral extension direction relative to the first slide 14A. The lateral extender 8 includes a driver such as an electric motor not shown in the drawings, and uses the driving force of this driver to laterally extend the first slide 14A in the lateral extension direction D relative to the base 13. The lateral extender 8 laterally extends the second slide 14B in the same lateral extension direction D relative to the first slide 14A, in conjunction with the lateral extension of the first slide 14A. The lateral extender 8 only needs to have a configuration that can laterally extend the elevation driver 11 in the lateral extension direction D, and may use a configuration other than the base 13 and one or more slides 14.

The cover 5a is provided on the-X side of the main body 4, and the cover 5b is provided on the +X side. The cover 5a and the cover 5b are each fixed to the support 3b and arranged so as to extend from the support 3b in the-Z direction. The pair of covers 5a, 5b provide a space in which the container 100 is accommodated, that is, an accommodation space AS.

The elevator 6 includes an elevation platform 20, a holder 21, and a rigidity changer 40. The elevation platform 20 is an example of the elevation body. The elevation body is not limited to the elevation platform 20, but may be any structural element that can be raised or lowered relative to the main body 4.

The other ends of the multiple suspenders 12 are fixed to the elevation platform 20. The elevation platform 20 is, for example, a plate-shaped structure, and is suspended by the multiple suspenders 12 so that its plane is parallel or substantially parallel to the horizontal plane. However, in the present example embodiment, the shape of the elevation platform 20 is not particularly limited.

The holder 21 is fixed to the lower surface of the elevation platform 20. The holder 21 holds a container 100. The holder 21 suspends and holds the container 100 by grasping the flange 100A of the container 100. While the method by which the holder 21 grasps the container 100 is not limited, it may do so by gripping from above or by clamping the container 100 from the left and right. The holder 21 includes, for example, a chuck that includes multiple claws 21a and is movable in the horizontal direction. The holder 21 moves the claws 21a to the underside of the flange 100A by the driving force of a motor or the like. Then, the elevation driver 11 winds up the suspenders 12, causing the holder 21 to rise, whereby the holder 21 holds the container 100 in a suspended state.

In the state where the holder 21 is holding the container 100 in the accommodation space AS, the rigidity changer 40 can switch between a first rigidity state in which the rigidity between the main body 4 and the holder 21 is a first rigidity, and a second rigidity state in which the rigidity is a second rigidity higher than the first rigidity. The rigidity changer 40 includes a first rigidity changer 22 and a second rigidity changer 23. In the rigidity changer shown in FIG. 1, the rigidity between the main body 4 and the holder 21 is both of the connection rigidity Ru between the main body 4 and the elevation platform 20, and the holding rigidity Rd between the elevation platform 20 and the flange 100A of the container 100.

The first rigidity changer 22 includes a mechanism that can adjust the connection rigidity Ru between the main body 4 and the elevation platform 20 while the holder 21 is holding the container 100. The first rigidity changer 22 is provided on the upper surface side of the elevation platform 20, for example. The first rigidity changer 22 includes, for example, a receiver 30 and a first elastic body 31.

The receiver 30 is provided on an upper portion of the elevation platform 20. The receiver 30 receives the lower surface of the elevation driver 11 on its upper surface. Specifically, when the overhead transport vehicle 1 stores the container 100 in the accommodation space AS, the upper surface of the receiver 30 comes in contact with the lower surface of the elevation driver 11. The receiver 30 is, for example, a plate-shaped structure, and is arranged so that its planes (upper and lower surfaces) are parallel or substantially parallel to the horizontal plane.

The first elastic body 31 is provided between the lower surface of the receiver 30 and the upper surface of the elevation platform 20. The first elastic body 31 includes, for example, one or more of a gel material, a rubber material, and a compression spring. The upper end of the first elastic body 31 is in contact with the receiver 30, while its lower end is in contact with the upper surface of the elevation platform 20.

The second rigidity changer 23 includes a mechanism that can adjust the holding rigidity Rd between the elevation platform 20 and the flange 100A of the container 100 while the holder 21 is holding the container 100. The second rigidity changer 23 includes, for example, a support 51, a presser 52, a connector 53, and a second elastic body 54.

The support 51 is provided at a lower portion of the elevation platform 20. The support 51 is arranged with its plane parallel or substantially parallel to the horizontal plane.

The presser 52 is provided at a lower portion of the support 51 and presses the container 100 held by the holder 21 downward. The presser 52 is, for example, a structural element that fits into a recess 100B in the flange 100A of the container 100 held by the holder 21, for positioning the holder 21 relative to the container 100.

The connector 53 connects the receiver 30 and the support 51 together. The connector 53 is, for example, a structural element that extends in the up-down direction, and one end thereof is fixed to the receiver 30 and the other end thereof is fixed to the support 51. The connector 53 can move in the up-down direction relative to the elevation platform 20. Therefore, the support 51 can also move in the up-down direction relative to the elevation platform 20. For example, when the receiver 30 moves downward, the connector 53 also moves downward. Therefore, the support 51 fixed to the other end of the connector 53 also moves downward relative to the elevation platform 20.

The second elastic body 54 is provided between the support 51 and the presser 52. In other words, the second elastic body 54 has one end connected to the support 51 and the other end connected to the presser 52. The second elastic body 54 biases the presser 52 downward. The second elastic body 54 includes, for example, one or more of a gel material, a rubber material, and a compression spring.

The controller 9 may include a processor such as a CPU (Central Processing Unit) or an MPU (Micro Processing Unit) and a non-volatile or volatile semiconductor memory (for example, RAM (Random Access Memory), ROM (Read Only Memory), flash memory, EPROM (Erasable Programmable Read Only Memory), or EEPROM (Electrically Erasable Programmable Read Only Memory) ). For example, the controller 9 may be a microcontroller such as an MCU.

The controller 9 is configured or programmed to control various operations of the overhead transport vehicle 1. The controller 9 is configured or programmed to control the traveling of the overhead transport vehicle 1 by controlling the traveling driver 2b. The controller 9 is configured or programmed to control a driver (for example, an electric motor) provided in the lateral extender 8 to control the laterally extending operation performed by the lateral extender 8.

The controller 9 is configured or programmed to control the elevation driver 11. For example, the controller 9 is configured or programmed to control the rotation of the elevation motor 120 to control the winding-up and feeding-out (unwinding) of the suspenders 12. In other words, the controller 9 is configured or programmed to control the position of the elevator 6 in the Z direction (hereinafter, referred to as “position of the elevator 6”) by controlling the rotation of the elevation motor 120. FIG. 2 is a diagram schematically showing lateral transferer of the overhead transport vehicle according to the present example embodiment. Lateral transfer refers to transferring the container 100 to a predetermined position by feeding out the suspenders 12 after the laterally extending operation. For example, the overhead transport vehicle 1 travels to a predetermined position (hereinafter, referred to as “transport position”) on the overhead track R with the container 100 accommodated in the accommodation space AS, and performs lateral transfer at the transport position.

When the holder 21 is holding the container 100 in the accommodation space AS, the controller 9 is configured or programmed to control the rotation of the elevation motor 120 to change the position of the elevator 6, thus operating the first rigidity changer 22 and the second rigidity changer 23. This allows the controller 9 to adjust both the connection rigidity Ru and the holding rigidity Rd. In other words, in a state where the upper surface of the receiver 30 is in contact with the lower surface of the elevation driver 11 while the container 100 is held by the holder 21, the controller 9 is configured or programmed to adjust both the connection rigidity Ru and the holding rigidity Rd by adjusting the position of the elevator 6.

The controller 9 changes both the connection rigidity Ru and the holding rigidity Rd according to the traveling state of the overhead transport vehicle 1. The traveling state includes, for example, at least one of the following the start of travel of the overhead transport vehicle 1 accommodating the container 100, a state where the speed of the overhead transport vehicle 1 is equal to or higher than a first threshold value (hereinafter, referred to as “first traveling state, the start of the stopping operation for the overhead transport vehicle 1 accommodating the container 100; a state where the speed of the overhead transport vehicle 1 is below a second threshold value (hereinafter, referred to as “second traveling state”), and a state where the overhead transport vehicle 1 is stationary (hereinafter, “stop state”). The second threshold value is lower than the first threshold value to create hysteresis, but may be the same value as the first threshold value.

The second traveling state may be a state where the overhead transport vehicle 1, traveling along the overhead track R while holding the container 100, slows down in order to stop, and the speed of the decelerating overhead transport vehicle 1 falls below the second threshold value that is lower than the first threshold value. The second traveling state may or may not include the state during the period from the start of travel f the overhead transport vehicle 1 until the speed of the overhead transport vehicle 1 reaches or exceeds the second threshold value.

For example, the controller 9 may be configured or programmed to determine whether the current traveling state of the overhead transport vehicle 1 is the first traveling state or the second traveling state. The controller 9 may be configured or programmed to determine whether the current traveling state of the overhead transport vehicle 1 is the first traveling state or the second traveling state, by directly measuring the speed of the overhead transport vehicle 1 using a speed sensor, for example. The controller 9 may be configured or programmed to, for example, determine whether the current traveling state of the overhead transport vehicle 1 is the first traveling state or the second traveling state, by indirectly acquiring the speed of the overhead transport vehicle 1 through measuring values such as the rotation speed of the traveling driver 2b or the voltage supplied to the traveling driver 2b.

Sections may be preliminarily set as follows: a first section where the overhead transport vehicle 1 travels at or above the speed of the first threshold value; a second section where the overhead transport vehicle 1 travels below the speed of the second threshold value; and a third section where the overhead transport vehicle 1 stops. The controller 9 may be configured or programmed to determine whether the traveling state of the overhead transport vehicle 1 is the first traveling state or the second traveling state by determining whether the current position of the overhead transport vehicle 1 is in the first section, the second section, or the third section. However, in the present example embodiment, the determination method is not particularly limited, as long as the traveling state of the overhead transport vehicle 1 can be directly or indirectly identified as the first traveling state or the second traveling state. The controller 9 may be configured or programmed to determine whether the overhead transport vehicle 1 is currently in the stop state on the basis of values such as the sensor results of the speed sensor mentioned above, the rotation speed of the traveling driver 2b, and the voltage supplied to the traveling driver 2b, or may determine that the overhead transport vehicle 1 is currently in the stop state when it detects that the position of the overhead transport vehicle 1 is within the third section.

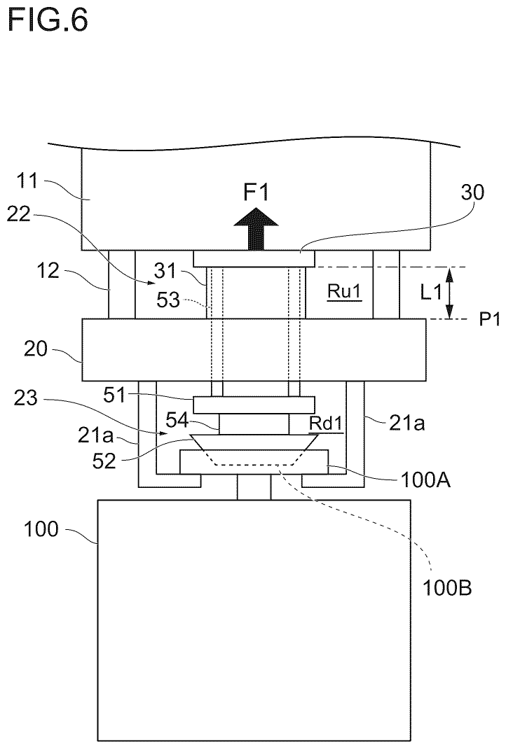

The controller 9 is configured or programmed to control the position of the elevator 6 so that, for example, both the connection rigidity Ru determined by the first rigidity changer 22 and the holding rigidity Rd determined by the second rigidity changer 23 are higher when in the second traveling state or when the overhead transport vehicle 1 is stationary than when in the first traveling state. For example, in the case where the traveling state of the overhead transport vehicle 1 is the first traveling state, the controller 9 is configured or programmed to control the connection rigidity Ru to a first connection rigidity Ru1 and the holding rigidity Rd to a first holding rigidity Rd1 by setting the position of the elevator 6 to a first position P1 (for example, see FIG. 6). The state where the connection rigidity Ru is controlled to the first connection rigidity Ru1 and the holding rigidity Rd is controlled to the first holding rigidity Rd1 may be referred to as “vibration suppression state”. The vibration suppression state is a state where vibration of the container 100 is reduced or prevented during travel. The vibration suppression state is an example of the first rigidity state.

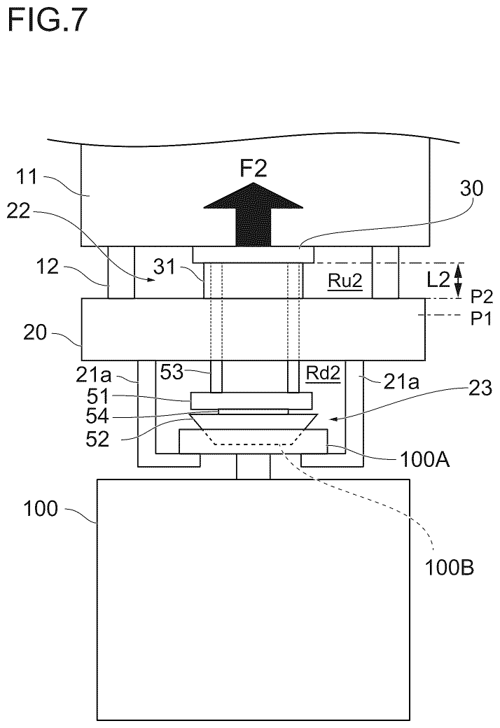

In the case where the traveling state of the overhead transport vehicle 1 is the second traveling state or where the overhead transport vehicle 1 is stationary, the position of the elevator 6 is set to a second position P2 (for example, see FIG. 7) that is higher than the first position P1, so that the connection rigidity Ru is set to a second connection rigidity Ru2 that is higher than the first connection rigidity Ru1, and the holding rigidity Rd is set to a second holding rigidity Rd2 that is higher than the first holding rigidity Rd1. The state where the connection rigidity Ru is controlled to the second connection rigidity Ru2 and the holding rigidity Rd is controlled to the second holding rigidity Rd2 may be referred to as “sway suppression state”. The sway suppression state is a state where the sway of the container 100 is reduced or prevented. The upper surface of the receiver 30 is in contact with the lower surface of the elevation driver 11 when the elevator 6 is positioned at the first position P1 or the second position P2. The sway suppression state is an example of the second rigidity state.

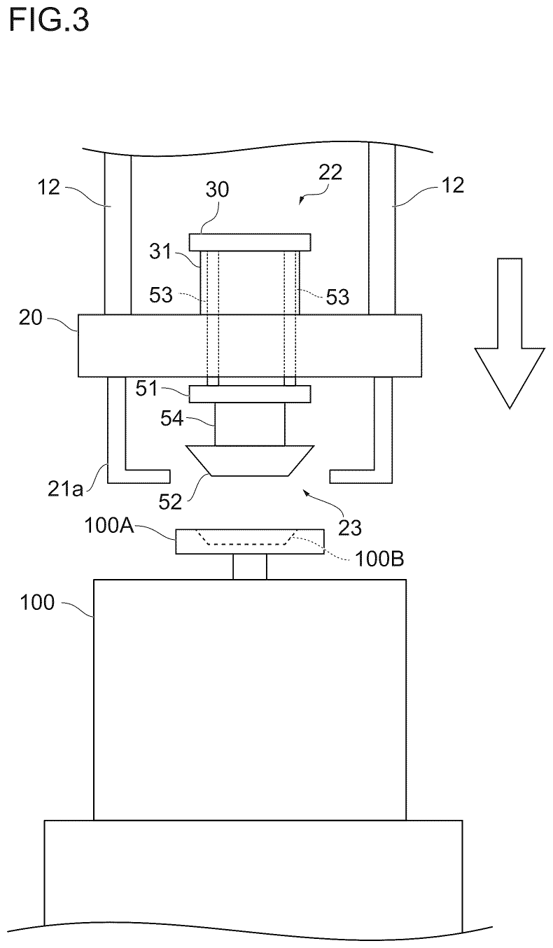

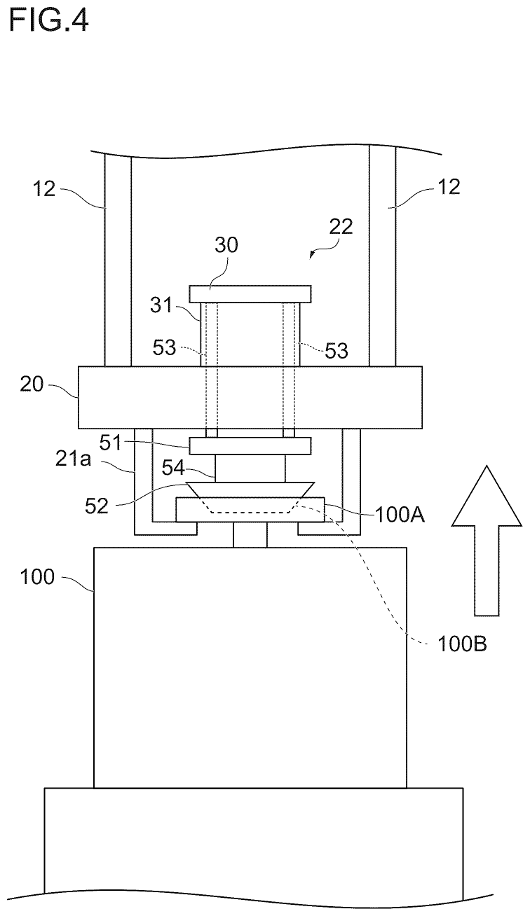

The holding operation of the overhead transport vehicle 1 will be described below. FIG. 3 is a diagram showing the overhead transport vehicle 1 in a state where it is not holding the container 100 (hereinafter, referred to as “initial state”). In the initial state shown in FIG. 3, the holder 21 is not holding the container 100, and the upper surface of the receiver 30 is not in contact the lower surface of the elevation driver 11. FIG. 4 is a diagram showing a state where the overhead transport vehicle 1 is holding the container 100.

When the overhead transport vehicle 1 is in the initial state, the elevation driver 11, controlled by the controller 9, feeds out the suspenders 12 to lower the elevator 6. As the elevator 6 descends, as shown in FIG. 4, the presser 52 fits into the recess 100B of the flange 100A, and the presser 52 rises relative to the holder 21, which descends under its own weight. Once the presser 52 has risen to a predetermined position, the elevation driver 11 stops lowering the elevator 6, as this indicates that the holder 21 has reached the holding position.

Once the elevator 6 stops descending, the holder 21 moves the claws 21a to the underside of the flange 100A on the basis of an instruction from the controller 9 to thus hold the container 100. Once the holder 21 holds the container 100, the elevation driver 11, controlled by the controller 9, winds up the multiple suspenders 12 to raise the elevator 6. The container 100 is accommodated in the accommodation space AS. Hereinafter, the state where the container 100 is accommodated in the accommodation space AS may be referred to as “accommodation state”.

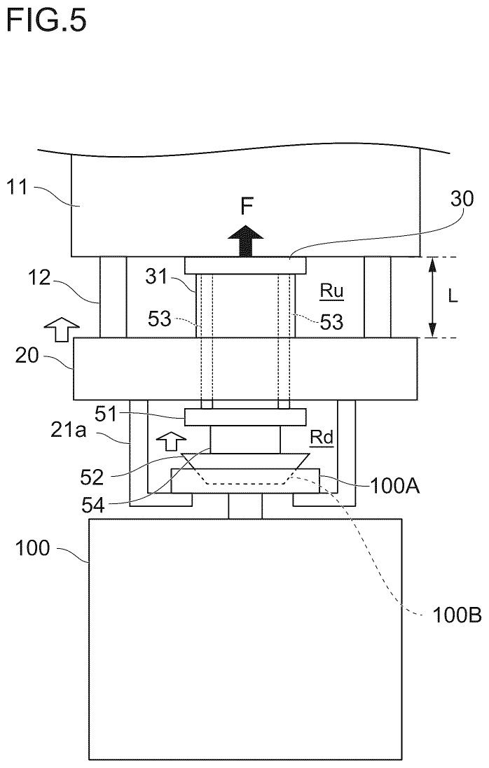

FIG. 5 is a diagram showing an example of the accommodation state according to the present example embodiment. In the accommodation state, the upper surface of the receiver 30 is in contact with the lower surface of the elevation driver 11. As the upper surface of the receiver 30 comes in contact with the lower surface of the elevation driver 11, the first rigidity changer 22 operates to increase the connection rigidity Ru between the main body 4 and the elevation platform 20. Specifically, when the upper surface of the receiver 30 is pressed against the lower surface of the elevation driver 11, the first elastic body 31 is compressed, and an elastic force in the up-down direction is generated according to the compression amount. In other words, by pressing the elevator 6 against the elevation driver 11 (main body 4), the first elastic body 31 is compressed, and an elastic force in the up-down direction is generated according to the compression amount. Using this elastic force, the first elastic body 31 biases the receiver 30 upward and the elevation platform 20 downward. The compression amount of the first elastic body 31 may be, for example, the length of the first elastic body 31 that has changed as a result of the upper surface of the receiver 30 being pressed against the lower surface of the elevation driver 11.

As the first elastic body 31, clamped between the elevation driver 11 and the elevation platform 20, is compressed, an elastic force is generated according to the compression amount, increasing the connection rigidity Ru between the elevation driver 11 and the elevation platform 20. A higher compression amount of the first elastic body 31 results in a higher connection rigidity Ru. The compression amount of the first elastic body 31 varies depending on the distance L between the elevation driver 11 and the elevation platform 20. In other words, as the elevation platform 20 moves upward and the distance L between the elevation driver 11 and the elevation platform 20 becomes shorter, the compression amount of the first elastic body 31 increases. Thus, the overhead transport vehicle 1 can change the compression amount of the first elastic body 31 by changing the distance L between the elevation driver 11 and the elevation platform 20, and as a result, can change the connection rigidity Ru.

As the upper surface of the receiver 30 is pressed against the lower surface of the elevation driver 11 and the first elastic body 31 is compressed, the elevation platform 20 moves upward. That is to say, as the first elastic body 31 is compressed, the second rigidity changer 23 operates, and the presser 52 is shifted upward relative to the support 51. As a result, the second elastic body 54 is compressed, and the holding rigidity Rd between the elevation platform 20 and the flange 100A of the container 100 increases. Specifically, an elastic force in the up-down direction is generated according to the compression amount of the second elastic body 54. The second elastic body 54 presses the presser 52 against the flange 100A with the elastic force according to the compression amount of the second elastic body 54.

Thus, as the second elastic body 54, clamped between the elevation platform 20 and the container 100, is compressed, an elastic force corresponding to the compression amount is generated, pressing the presser 52 against the flange 100A. As a result, the holding rigidity Rd between the elevation platform 20 and the flange 100A of the container 100 increases. A higher compression amount of the second elastic body 54 results in a higher holding rigidity Rd.

The compression amount of the second elastic body 54 varies depending on the distance between the support 51 and the presser 52. In the example shown in FIG. 5, the distance between the support 51 and the presser 52 varies depending on the distance L between the elevation driver 11 and the elevation platform 20. Therefore, the compression amount of the second elastic body 54, as with that of the first elastic body 31, varies depending on the distance L between the elevation driver 11 and the elevation platform 20. In other words, by pressing the elevator 6 against the elevation driver 11 (main body 4), not only the first elastic body 31 but also the second elastic body 54 is compressed.

As the elevation platform 20 moves upward and the distance L between the elevation driver 11 and the elevation platform 20 becomes shorter, the compression amount of the second elastic body 54 increases. Thus, the overhead transport vehicle 1 can also change the compression amount of the second elastic body 54 by changing the distance L between the elevation driver 11 and the elevation platform 20, and as a result, can change the holding rigidity Rd. Here, in the configuration exemplified in FIG. 5, changing the distance L between the elevation driver 11 and the elevation platform 20 is equivalent to changing the pressing force F, which is the force pressing the elevator 6 against the elevation driver 11 (main body 4). Therefore, the overhead transport vehicle 1 can change the compression amount of the first elastic body 31 and the compression amount of the second elastic body 54 by changing the pressing force F, and as a result, the connection rigidity Ru and the holding rigidity Rd can be changed.

A method for controlling the connection rigidity Ru and the holding rigidity Rd will be described below. FIG. 6 is a diagram for describing the connection rigidity Ru and the holding rigidity Rd in the vibration suppression state. FIG. 7 is a diagram for describing the connection rigidity Ru and the holding rigidity Rd in the sway suppression state.

When the container 100 is in the accommodation state, in the case of the first traveling state where the speed of the overhead transport vehicle is equal to or higher than the first threshold value, the controller 9, as exemplified in FIG. 6, places the overhead transport vehicle 1 in the vibration suppression state by controlling the pressing force F to a first pressing force F1. Specifically, in the case where the traveling state is the first traveling state, the controller 9 controls the position of the elevator 6 to the first position P1 to press the upper surface of the receiver 30 against the lower surface of the elevation driver 11 with the first pressing force F1. The distance L between the elevation driver 11 and the elevation platform 20 in the vibration suppression state is referred to as “first distance L1”. In the vibration suppression state, the compression amount of the first elastic body 31 becomes a first compression amount, and the compression amount of the second elastic body 54 becomes the first compression amount. Accordingly, the connection rigidity Ru becomes the first connection rigidity Ru1 corresponding to the first compression amount, and the holding rigidity Rd becomes the first holding rigidity Rd1 corresponding to the first compression amount.

When the container 100 is in the accommodation state, in the case of the second traveling state where the speed of the overhead transport vehicle 1 is lower than a second threshold value that is lower than the first threshold value, the controller 9 controls the pressing force F to a second pressing force F2 to place the overhead transport vehicle 1 in the sway suppression state. The second pressing force F2 is greater than the first pressing force F1.

Specifically, when the overhead transport vehicle 1 is in the second traveling state, the controller 9 controls the distance between the elevation driver 11 and the elevation platform 20 to a second distance L2 that is shorter than the first distance L1 by changing, in stages, the position of the elevator 6 to the second position P2 that is higher than the first position P1. The sway suppression state shown in FIG. 7 is a state where the position of the elevator 6 is raised from the first position P1 to the second position P2 by winding up the multiple suspenders 12 by a predetermined amount from the vibration suppression state shown in FIG. 6.

In the sway suppression state, the compression amount of the first elastic body 31 and the compression amount of the second elastic body 54 become a second compression amount (>first compression amount) that is greater than the first compression amount. Therefore, the connection rigidity Ru becomes the second connection rigidity Ru2 corresponding to the second compression amount, and the second connection rigidity Ru2 in the sway suppression state becomes greater than the first connection rigidity Ru1 in the vibration suppression state. The holding rigidity Rd becomes a second holding rigidity Rd2 corresponding to the second compression amount, and the second holding rigidity Rd2 in the sway suppression state becomes greater than the first holding rigidity Rd1 in the vibration reduced or prevented state.

Thus, in the first traveling state, the state of the overhead transport vehicle 1 is switched to the vibration suppression state, and in the second traveling state, the state of the overhead transport vehicle 1 is switched to the sway suppression state. Specifically, the overhead transport vehicle 1 travels with the position of the elevator 6 lowered from the second position P2 to the first position P1 so that in the first traveling state the pressing force F becomes the first pressing force F1, which is less than the second pressing force F2 (FIG. 6). The overhead transport vehicle 1 travels or stops with the position of the elevator 6 raised from the first position P1 to the second position P2 so that in the second traveling state the pressing force F becomes the second pressing force F2, which is greater than the second pressing force F1. For example, when switching from the vibration suppression state to the sway suppression state, the pressing force F is changed in stages from the first pressing force Fl to the second pressing force F2. In other words, switching from the vibration suppression state to the sway suppression state, or switching from the sway suppression state to the vibration suppression state, may be performed in stages rather than discontinuously.

The vibration and sway of the container 100 held by the overhead transport vehicle 1 will be described below. When the overhead transport vehicle 1 is traveling along the overhead track R with the container 100 accommodated in the accommodation space AS, vibration f the overhead transport vehicle 1 may be transmitted to the container 100, causing the container 100 to vibrate. For example, when the overhead transport vehicle 1 travels, the wheels 2a rolling on the overhead track R may be subjected to impacts at joints (connections) or the like of the overhead track R. For example, when there is a step at a joint of the overhead track R, the wheels 2a may be subjected to some impact when the overhead transport vehicle 1 travels over the step. As an impact is applied to the wheel 2a, the impact causes vibration in the entire overhead transport vehicle 1, and as a result, the container 100 may be subjected to the vibration. For this reason, it is desirable to reduce or prevent such vibration as much as possible.

When the overhead transport vehicle 1 performs a transfer operation such as laterally extending or lowering the container 100 at a transfer position on the overhead track R, the overhead transport vehicle 1 stops at the transfer position and then starts the transfer operation. Here, during the transfer operation, the container 100 may sway considerably in the traveling direction or the lateral direction. If the transfer operation to the load port is started while the container 100 is swaying considerably, the container 100 may ride up onto the carrier guide at the load port. Therefore, while it is possible to wait at the transport position until the sway of the container 100 subsides before starting the transfer operation, doing so would increase the transfer time and reduce transport capacity. Therefore, it is desirable to reduce or prevent sway of the container 100 as much as possible during the transfer operation.

Here, consider a case where the pressing force F is controlled to remain constant at all times, so that the connection rigidity Ru and the holding rigidity Rd are always maintained constant regardless of the traveling state. For example, in order to reduce or prevent sway of the container 100 during the transfer operation, the pressing force F is increased to maintain the connection rigidity Ru and the holding rigidity Rd at a high level. In such a case, the sway of the container 100 during the transfer operation can be reduced or prevented, but the vibration of the container 100 during travel cannot be reduced or prevented and increases. Specifically, when the connection rigidity Ru and the holding rigidity Rd are high, vibrations are easily transmitted from the main body 4 to the container 100 through the elevator 6. That is to say, setting a high connection rigidity Ru and holding rigidity Rd to reduce or prevent the sway of the container 100 during a transfer operation will prevent the suppression of vibrations while the vehicle is traveling. Conversely, setting a low connection rigidity Ru and holding rigidity Rd to reduce or prevent the vibration of the container 100 during travel will prevent the suppression of sway while the transfer operation is performed.

If the connection rigidity Ru and the holding rigidity Rd are maintained constant at all times regardless of the traveling state, it is only possible to reduce or prevent either the vibration of the container 100 during travel or its sway during a transfer operation, but not both.

In the configuration of the example of the present example embodiment, the overhead transport vehicle 1 does not control the pressing force F to remain constant at all times, but changes the pressing force F according to the traveling state of the overhead transport vehicle 1. In other words, the overhead transport vehicle 1 changes the connection rigidity Ru and the holding rigidity Rd according to the traveling state of the overhead transport vehicle 1. For example, in the overhead transport vehicle 1, during travel in the first traveling state, by setting the pressing force F to the first pressing force F1, the connection rigidity Ru and the holding rigidity Rd are reduced, resulting in the vibration suppression state where vibration caused by the impact mentioned above is less likely to be transmitted to the container 100. On the other hand, in the overhead transport vehicle 1, when a stopping operation starts or traveling has stopped, the pressing force F is set to the second pressing force F2, which is higher than the first pressing force F1 to increase the connection rigidity Ru and the holding rigidity Rd and resulting in the sway suppression state where the sway of the container 100 is reduced or prevented. As a result, both the vibration of the container 100 during travel and the sway of the container 100 during the transfer operation are effectively reduced or prevented.

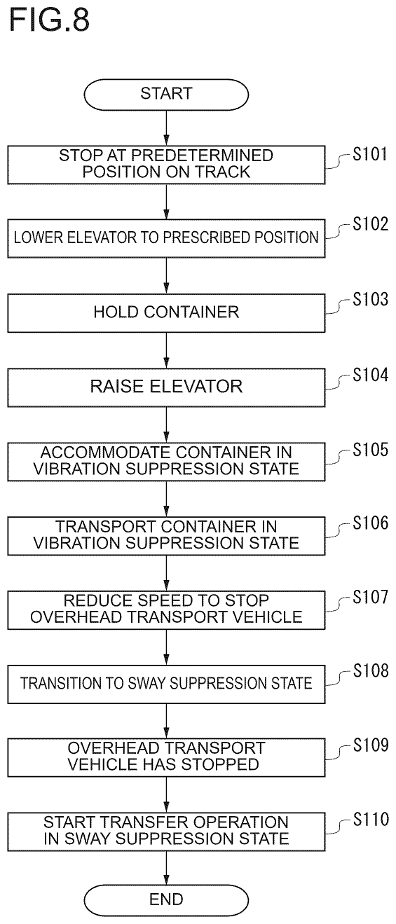

An example of the flow of operations of the overhead transport vehicle 1 according to the present example embodiment will be described below. FIG. 8 is a diagram for describing an example of the flow of operations of the overhead transport vehicle 1 according to the present example embodiment. First, the overhead transport vehicle 1 travels along the overhead track R without holding a container 100, and stops at a predetermined position on the overhead track R (Step S101). At the predetermined position on the overhead track R, as the overhead transport vehicle 1 uses the elevation driver 11 to lower the elevator 6 to a designated position (Step S102), the presser 52 fits into the recess 100B of the flange 100A, and the holder 21 reaches the holding position. Once the holder 21 reaches the holding position, the elevator 6 stops descending, and the holder 21 holds the container 100 (Step S103). Once the holder 21 holds the container 100, the overhead transport vehicle 1 raises the elevator 6 (Step S104).

Here, when the container 100 is accommodated in the accommodation space AS, the overhead transport vehicle 1 sets the pressing force F to the first pressing force F1, and this sets the connection rigidity Ru to the first connection rigidity Ru1 and the holding rigidity Rd to the first holding rigidity Rd1. In other words, when the container 100 is accommodated in the accommodation space AS, the controller 9 controls the overhead transport vehicle 1 to the vibration suppression state by setting the pressing force F to the first pressing force F1 (Step S105). The first connection rigidity Ru1 and the first holding rigidity Rd1 are adjusted, for example, so that vibration of the container 100 during travel falls within an allowable range.

The overhead transport vehicle 1 travels on the overhead track R toward the transport position while maintaining the pressing force F at the first pressing force F1 (Step S106). As the overhead transport vehicle 1 approaches the transport position, the controller 9 gradually reduces the speed of the overhead transport vehicle 1 so that the vehicle will stop at the transfer position (Step S107). Then, when the speed of the overhead transport vehicle 1 becomes equal to or lower than the second threshold value, the controller 9 changes the pressing force F from the first pressing force F1 to the second pressing force F2.

When the pressing force F is changed from the first pressing force F1 to the second pressing force F2, the compression amount of the first elastic body 31 and the compression amount of the second elastic body 54 both increase, so that the connection rigidity Ru becomes the second connection rigidity Ru2, which is greater than the first connection rigidity Ru1, and the holding rigidity Rd becomes the second holding rigidity Rd2, which is greater than the first holding rigidity Rd1. That is to say, when the speed of the overhead transport vehicle 1 becomes equal to or lower than the second threshold value, the controller 9 changes the pressing force F to the second pressing force F2 to transition the overhead transport vehicle 1 from the vibration suppression state to the sway suppression state (Step S108). The second connection rigidity Ru2 and the second holding rigidity Rd2 are adjusted, for example, so that sway of the container 100 falls within an allowable range.

Once the overhead transport vehicle 1 stops at the transport position (Step S109), the lateral extender 8 moves the elevation platform 20 laterally (Step S110). Here, the pressing force F is maintained at the second pressing force F2 even when the overhead transport vehicle 1 is stationary at the transport position. Therefore, the lateral extender 8 moves the elevation platform 20 laterally in the state where the connection rigidity Ru is maintained at the second connection rigidity Ru2 and the holding rigidity Rd is maintained at the second holding rigidity Rd2. In other words, the lateral extender 8 moves the elevation platform 20 laterally when the overhead transport vehicle 1 is in the sway suppression state. This makes it possible to effectively reduce or prevent the sway of the container 100 during the laterally extending operation.

The overhead transport vehicle 1 does not necessarily have to transition to the vibration suppression state in Step S105 of FIG. 8. For example, in Step S106, when the speed of the overhead transport vehicle 1 becomes equal to or higher than the first threshold value, the controller 9 may cause the overhead transport vehicle 1 to transition to the vibration suppression state by setting the pressing force F to the first pressing force F1. In such a case, when the elevator 6 is raised to accommodate the container 100 in the accommodation space AS in Step S105, the controller 9 may control the overhead transport vehicle 1 to the sway suppression state. The overhead transport vehicle 1 may start traveling in the sway suppression state in Step S106. Then, once the speed of the overhead transport vehicle 1 reaches the first threshold value or higher, the overhead transport vehicle 1 may be transitioned from the sway suppression state to the vibration suppression state by adjusting the pressing force F to the first pressing force F1.

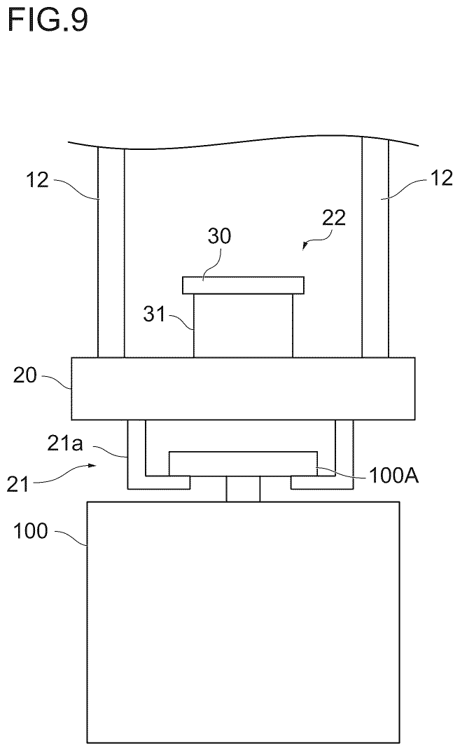

The rigidity changer 40 of the present example embodiment described above includes the first rigidity changer 22 and the second rigidity changer 23, however, is not limited to this configuration. For example, the rigidity changer 40 may include either the first rigidity changer 22 or the second rigidity changer 23. FIG. 9 is a diagram showing a first modified example of the rigidity changer 40. The rigidity changer 40 of the first modified example shown in FIG. 9 is the first rigidity changer 22.

In the first modified example, the rigidity between the main body 4 and the holder 21 is the connection rigidity Ru. In the overhead transport vehicle 1 of the first modified example, in the state where the holder 21 is holding the container 100, the connection rigidity Ru, which is the rigidity between the elevation driver 11 and the elevation platform 20, is changed according to the traveling state of the overhead transport vehicle 1, including the stop state. In the vibration suppression state in the first modified example, the connection rigidity Ru is the first connection rigidity Ru1. In the sway suppression state in the first modified example, the connection rigidity Ru is the second connection rigidity Ru2. Even in the first modified example, it is possible to effectively reduce or prevent both the vibration of the container 100 during travel and the sway of the container 100 during transfer operations.

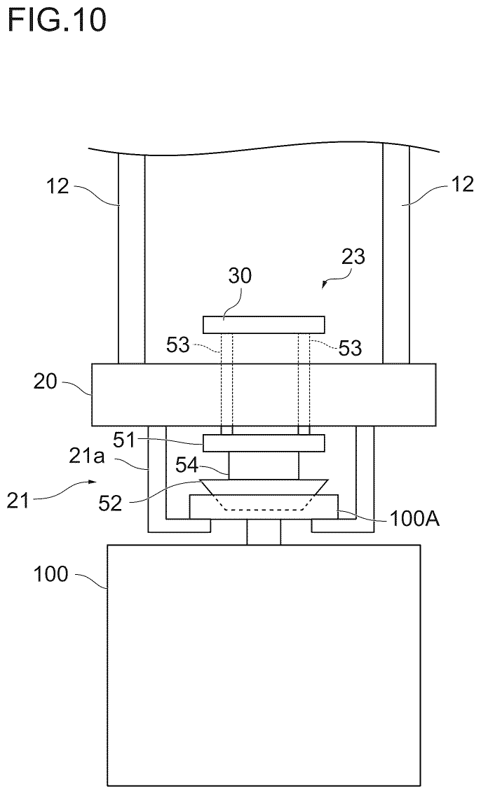

FIG. 10 is a diagram showing a second modified example of the rigidity changer 40. The rigidity changer 40 of the second modified example shown in FIG. 10 is the second rigidity changer 23. The second rigidity changer 23 of the second modified example further includes a receiver 30, for example.

In the second modified example, the rigidity between the main body 4 and the holder 21 is the holding rigidity Ru. In the overhead transport vehicle 1 of the second modified example, in the state where the holder 21 is holding the container 100, the holding rigidity Rd, which is the rigidity between the elevation platform 20 and the container 100, is changed according to the traveling state of the overhead transport vehicle 1, including the stop state. In the vibration suppression state in the second modified example, the holding rigidity Rd is the first holding rigidity Rd1. In the sway suppression state in the second modified example, the holding rigidity Rd is the second holding rigidity Rd2. Even in the second modified example, it is possible to effectively reduce or prevent both the vibration of the container 100 during travel and the sway of the container 100 during transfer operations.

Thus, in the overhead transport vehicle 1 of the present example embodiment, in the state where the holder 21 is holding the container 100, either or both of the connection rigidity Ru and the holding rigidity Rd are changed according to the traveling state of the overhead transport vehicle 1, including the stop state. With such a configuration, both vibration and sway can be effectively reduced or prevented.

It should be noted that the first rigidity changer 22 and the second rigidity changer 23 may each be independently controllable. For example, a first motor that operates the first rigidity changer 22 and a second motor that operates the second rigidity changer 23 may be provided, and the controller 9 may change the connection rigidity Ru by operating the first motor and change the holding rigidity Rd by controlling the second motor.

The above example embodiments may have the following configurations.

### Configuration 1

An overhead transport vehicle 1 to travel along an overhead track R while holding an article (container 100), the overhead transport vehicle including a traveler 2 to travels along the overhead track R, a main body 4 to move along the overhead track R together with the traveler 2, an elevation platform 20 suspended from the main body 4 to ascend and descend relative to the main body 4, a holder 21 that is fixed to a lower portion of the elevation platform 20 to hold the article (container 100), and a rigidity changer 40 to switch between a first rigidity state (vibration suppression state) in which a rigidity between the main body 4 and the holder 21 is a first rigidity, and a second rigidity state in which the rigidity is a second rigidity higher than the first rigidity, wherein the rigidity changer 40 is configured to switch between the first rigidity state (vibration suppression state) and the second rigidity state (sway suppression state) according to a traveling state of the overhead transport vehicle 1.

### Configuration 2

The overhead transport vehicle according to configuration 1, wherein the rigidity changer is configured to switch to the first rigidity state (vibration suppression state) when a speed of the overhead transport vehicle 1 is equal to or higher than a first speed, and switch to the second rigidity state (sway suppression state) when the speed of the overhead transport vehicle 1 is equal to or less than a second speed lower than the first speed, or when the overhead transport vehicle is stationary.

### Configuration 3

The overhead transport vehicle according to configuration 1 or 2, wherein the rigidity is either one or both of a connection rigidity Ru, which is a rigidity between the main body 4 and the elevation platform 20 and a holding rigidity Rd, which is a rigidity between the elevation platform 20 and the article (container 100), in a state where the holder 21 is holding the article (container 100).

### Configuration 4

The overhead transport vehicle according to any one of configurations 1 to 3, wherein the rigidity changer 40 includes an elastic body (first elastic body 31) provided between the main body 4 and an upper portion of the elevation platform 20, the main body 4 includes an elevation driver 11 to adjust a compression amount of the elastic body by adjusting a position of the elevation platform 20 and to change the connection rigidity Ru by changing the compression amount of the elastic body.

### Configuration 5

The overhead transport vehicle according to any one of configurations 1 to 3, wherein the rigidity changer includes a support 51 that is provided at a lower portion of the elevation platform 20 and movable in an up-down direction according to an ascending/descending operation of the elevation platform 20, a presser 52 that is provided at a lower portion of the support to press the article (container 100) held by the holder 21 downward, an elastic body (second elastic body 54) provided between the support and the presser, wherein the main body 4 includes an elevation driver 11 to adjust a compression amount of the elastic body by adjusting a position of the elevation platform 20 and to change the holding rigidity Rd by changing the compression amount of the elastic body.

### Configuration 6

The overhead transport vehicle according to any one of configurations 1 to 3, wherein the rigidity changer includes a receiver 30 provided at an upper portion of the elevation platform 20, a first elastic body 31 provided between the receiver 30 and the upper portion of the elevation platform, a support 51 provided at a lower portion of the elevation platform 20, a connector 53 to connect the receiver and the support, a presser 52 that is provided at a lower portion of the support to press the article (container 100) held by the holder 21 downward, and an second elastic body 54 provided between the support and the presser, wherein the main body 4 includes an elevation driver 11 to adjust the compression amount of the first elastic body 31 and the second elastic body 54 by adjusting the position of the elevation platform 20 with the receiver in contact with the main body 4, an increase in the compression amount of the first elastic body 31 and the second elastic body 54 causes an increase in the connection rigidity Ru and the holding rigidity Rd become, and when in the first rigidity state (vibration suppression state), the compression amount of the first elastic body 31 and the second elastic body 54 is controlled to be a first compression amount, and when in the second rigidity state, the compression amount of the first elastic body 31 and the second elastic body 54 is controlled to be a second compression amount that is higher than the first compression amount.

### Configuration 7

The overhead transport vehicle according to any one of configurations 1 to 6, wherein the main body 4 includes a lateral extender 8 to move the elevation platform 20 laterally from the traveling direction and to move the elevation platform 20 laterally when in the second rigidity state.

One or more of the elements, features, etc., described in the above example embodiments may be omitted in some cases. Furthermore, one or more the elements, features, etc., described in the above example embodiments may be combined where appropriate. The order of executing procedures included in the example embodiments can be implemented in an arbitrary order unless the result of the previous procedure is used in the following procedure. While operations in the above example embodiments have been described with expressions such as “first”, “next”, and “subsequently” for the sake of convenience, the operations need not always be implemented in that order.

The entire contents of Japanese Patent Application No. 2023-093147 and all documents cited in the detailed description of the present invention are incorporated herein by reference to the extent permitted by law.

While example embodiments of the present invention have been described above, it is to be understood that variations and modifications will be apparent to those skilled in the art without departing from the scope and spirit of the present invention. The scope of the present invention, therefore, is to be determined solely by the following claims.

1-7. (canceled)

8. An overhead transport vehicle to travel along an overhead track while holding an article, the overhead transport vehicle comprising:
a traveler to travel along the overhead track;
a main body to move along the overhead track together with the traveler;
an elevation body suspended from the main body to ascend and descend relative to the main body;
a holder fixed to a lower portion of the elevation body to hold the article; and
a rigidity changer to switch between a first rigidity state in which a rigidity between the main body and the holder is a first rigidity, and a second rigidity state in which a rigidity is a second rigidity higher than the first rigidity; wherein
the rigidity changer is configured to switch between the first rigidity state and the second rigidity state according to a traveling state of the overhead transport vehicle.

9. The overhead transport vehicle according to claim 8, wherein the rigidity changer is configured to switch to the first rigidity state when a speed of the overhead transport vehicle is equal to or higher than a first speed, and to switch to the second rigidity state when the speed of the overhead transport vehicle is equal to or less than a second speed lower than the first speed, or when the overhead transport vehicle is stationary.

10. The overhead transport vehicle according to claim 8, wherein the rigidity is either one or both of a connection rigidity, which is a rigidity between the main body and the elevation body and a holding rigidity, which is a rigidity between the elevation body and the article, in a state where the holder is holding the article.

11. The overhead transport vehicle according to claim 10, wherein
the rigidity changer includes an elastic body provided between the main body and an upper portion of the elevation body; and
the main body includes an elevation driver to adjust a compression amount of the elastic body by adjusting a position of the elevation body and to change the connection rigidity by changing the compression amount of the elastic body.

12. The overhead transport vehicle according to claim 10, wherein
the rigidity changer includes:
a support that is provided at a lower portion of the elevation body and movable in an up-down direction according to an ascending/descending operation of the elevation body;
a presser that is provided at a lower portion of the support to press the article held by the holder downward; and
an elastic body provided between the support and the presser; wherein
the main body includes an elevation driver to adjust a compression amount of the elastic body by adjusting a position of the elevation body and to change the holding rigidity by changing the compression amount of the elastic body.

13. The overhead transport vehicle according to claim 10, wherein
the rigidity changer includes:
a receiver provided at an upper portion of the elevation body;
a first elastic body provided between the receiver and the upper portion of the elevation body;
a support provided at a lower portion of the elevation body;
a connector to connect the receiver and the support;
a presser that is provided at a lower portion of the support to press the article held by the holder downward; and
a second elastic body provided between the support and the presser; wherein
the main body includes an elevation driver to adjust the compression amount of the first elastic body and the second elastic body by adjusting the position of the elevation body with the receiver in contact with the main body;
an increase in the compression amount of the first elastic body and the second elastic body causes an increase in the connection rigidity and the holding rigidity; and
when in the first rigidity state, the compression amount of the first elastic body and the second elastic body is controlled to be a first compression amount, and when in the second rigidity state, the compression amount of the first elastic body and the second elastic body is controlled to be a second compression amount that is higher than the first compression amount.

14. : The overhead transport vehicle according to claim 8, wherein the main body includes a lateral extender to move the elevation body laterally from the traveling direction and to move the elevation body laterally when in the second rigidity state.
